(19) United States
(12) Patent Application Publication
(10) Pub. No.: US 2005/0056867 A1
(43) Pub. Date: Mar. 17, 2005

(54) Surface photovoltage-based sensing of molecules

(76) Inventors: Krzysztof Nauka, Redwood City, CA (US); Zhiyong Li, Mountain View, CA (US); Theodore I. Kamins, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/665,189

(22) Filed: Sep. 16, 2003

(51) Int. Cl. H01L 29/768

(52) U.S. Cl. 257/222

(57) ABSTRACT

Surface photovoltage is used for molecule sensing. The sensing is performed by exposing a surface of a semiconductor to molecules, and sensing a change in surface photovoltage of the semiconductor. Chemical and biological sensors may be based on such sensing.

### BACKGROUND

Chemical sensors have been used in applications such as critical care, safety, industrial hygiene, process controls, product quality controls, human comfort controls, emissions monitoring, automotive, clinical diagnostics, and home. safety alarms. Biological sensors have been used in applications ranging from medicine and food control to environmental monitoring. More recently, chemical and biological sensors are being used for homeland security.

Conventional chemical and biological sensors are usually designed around a specific physical or chemical phenomenon and, therefore, are capable of sensing only a single molecule or a small group of molecules. Thus, sensing in an environment where a variety of molecules could be present requires costly application of a variety of sensors operating according to different physical or chemical phenomena, having different response times, reliability, and accuracy.

It is desirable to have a single platform sensor that can be easily adapted for inexpensive, reliable, and fast sensing of a large variety of chemical and biological species. For homeland security, it is also desirable to perform such sensing in real time.

### SUMMARY

According to one aspect of the present invention, molecule sensing is performed by exposing a surface of a semiconductor to molecules, and sensing a change in surface photovoltage of the semiconductor. Chemical and biological sensors may be based on such sensing.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is an illustration of a molecule sensor according to an embodiment of the present invention.

FIG. 2 is an illustration of a different electrode structure for the molecule sensor.

FIGS. 3 and 4 are illustrations of different ways of refreshing the molecule sensor.

FIG. 5 is an illustration of a system including an array of molecule sensors according to an embodiment of the present invention.

FIGS. 6 and 7 are illustrations of methods of fabricating a molecule sensor array according to different embodiments of the present invention.

### DETAILED DESCRIPTION

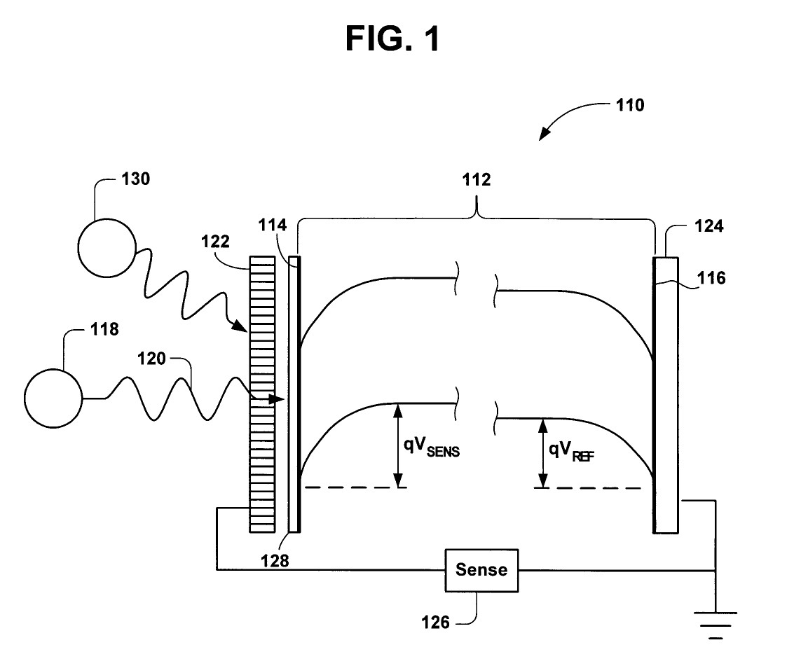

Referring to FIG. 1, a molecule sensor 110 includes a semiconductor 112 having a sensing surface 114 and a reference surface 116 opposite the sensing surface 114. The semiconductor 112 is not limited to any particular shape. For example, the semiconductor 112 could have the shape of a slab. The semiconductor 112 may include one or more materials, with the material defining the sensing surface 114 exhibiting a non-zero potential surface barrier. Many common semiconductors, both elemental (silicon, germanium, carbon) and compound (gallium arsenide, indium phosphide, gallium phosphide) exhibit this property. Thus, the semiconductor 112 may include a single semiconductor material; a stack of chemically different semiconductor materials (e.g., including one or more heterojunctions); a stack of the same semiconductor material but with different electrical properties (e.g., p/p+, n/n+, p/n junctions); etc.

The semiconductor 112 has a valence band with a highest energy (Eᵥ) and a conduction band with a lowest energy (E_{c}) that depend upon the crystalline structure of the semiconductor 112, and a bandgap equal to the difference between E_{c} and Eᵥ. (The breaks in the bands indicate that the semiconductor 112 may include more than one material.) Band bending occurring in the vicinity of the surfaces 114 and 116 of the semiconductor 112 is a natural consequence of the periodicity perturbation by a crystal-terminating surface. The intrinsic surface charges from the periodicity perturbation introduce the band bending and the corresponding space charge regions near the surfaces 114 and 116. The surface potential barriers (V_{SENS} and V_{REF}) describe the magnitude of the band bending at the sensing and reference surfaces 114 and 116 (V_{SENS} and V_{REF} correspond to the energy barriers qV_{SENS} and qV_{REF} shown in FIG. 1). The surface charges and the corresponding surface potential barriers (V_{SENS} and V_{REF}) can be further modified by external factors such as charged adsorbed species and by-products of interaction between the semiconductor surface and ambient species.

The molecule sensor 110 further includes a light source 118 for illuminating the sensing surface 114 during operation of the molecule sensor 110. Photon energy of the light source 118 is greater than or equal to the semiconductor bandgap in the vicinity of the sensing surface 114. When light 120 from the light source 118 is incident at the sensing surface 114, non-equilibrium electron-hole pairs (charge carriers) are generated in the vicinity of the sensing surface 114. These electrical charges change the potential distribution within the surface region of the semiconductor 112 in such fashion that a decrease occurs in the surface potential barrier (V_{SENS}) at the sensing surface 114 and an increase occurs in a measurable potential difference (V_{SENS-dark}−V_{SENS-light}) between the illuminated and non-illuminated conditions. This potential difference is called the surface photovoltage. Increasing the light intensity causes a further decrease of the potential barrier (V_{SENS}) at the sensing surface 114. The potential barrier (V_{SENS}) at the sensing surface 114 vanishes when the light intensity is high enough, whereby the surface photovoltage V_{sPv} is at its maximum value. This maximum value corresponds to V_{SENS-dark}.

Thus, if SPV is measured, the measured SPV corresponds to the height of V_{SENS-dark}, which in turn is related to the intrinsic semiconductor properties and extrinsic factors modifying the sensing surface barrier, such as byproducts of the surface reaction with ambient or species physisorbed on the surface.

The molecule sensor 110 is operated by exposing the sensing surface 114 to molecules (e.g., exposing the sensing surface to a gas, exposing the sensing surface to a liquid), and illuminating the sensing surface 114 with appropriately intense photon flux while sensing the surface photovoltage (SPV). Certain molecules react with the exposed sensing surface 114. For example, certain molecules form a stable chemical bond at the sensing surface 114 or are adsorbed by physisoption.

These certain molecules either carry net electrical charges or exhibit non-symmetric charge distribution within the molecule that can change the net charge within the semiconductor 112 near its sensing surface 114, thus changing the SPV. This change in SPV can be detected and used to recognize the presence of those certain molecules. For example, a first type of molecule can increase the surface barrier, while a second type of molecule causes it to decrease.

A signal related to SPV can be detected by using a non-contact electrode 122. The non-contact electrode 122 is suspended above the sensing surface 114 at a distance that is small enough to facilitate capacitive coupling to the sensing surface 114, but large enough to allow uninterrupted interactions between molecules and the sensing surface 114. The non-contact electrode 122 can be transparent to the light 120 so the sensing surface 114 can be illuminated through the non-contact electrode 122. In the alternative, the non-contact electrode 122 can be non-transparent to the light 120, in which case the sensing surface 114 can be illuminated by shining the light 120 at an angle into the gap between the non-contact electrode 122 and the sensing surface 114.

A reference electrode 124, in contact with the reference surface 116, is also used. AC light modulation can improve the sensitivity when the SPV signal is detected with a lock-in amplifier 126. An exemplary lock-in amplifier 126 includes an AC reference source, a preamplifier, and a synchronous demodulator followed by a low-pass-filter. The SPV signal is initially amplified and then fed into the demodulator. The demodulator multiplies the reference and measured SPV signals, significantly enhancing the signal at the frequency corresponding to the AC reference, while the low-pass filter eliminates the noise present at the output of demodulator.

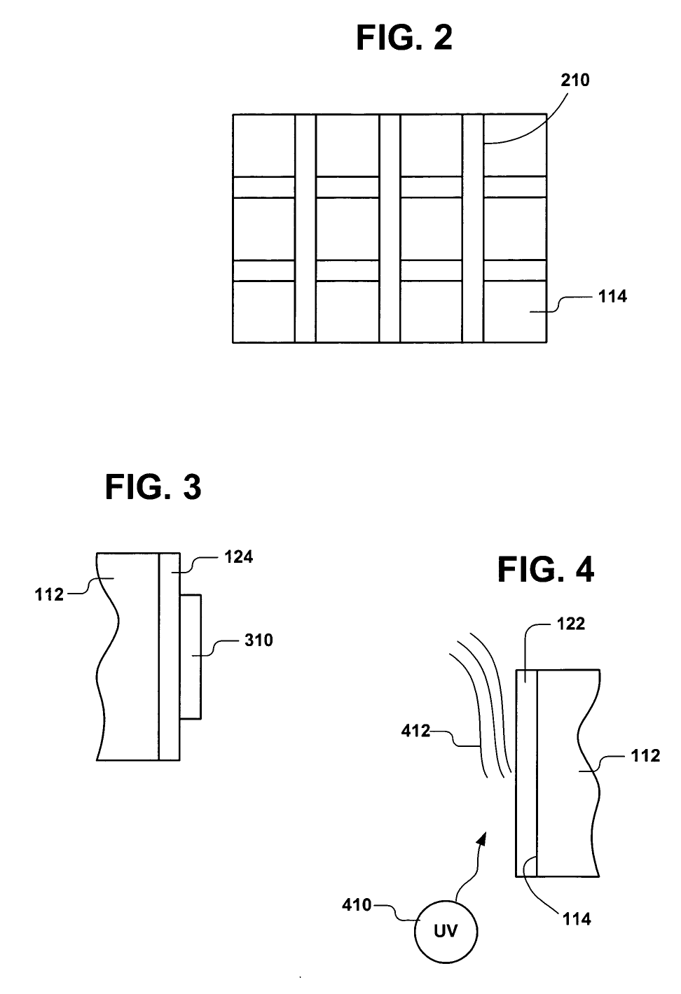

FIG. 2 shows an alternative to the non-contact electrode. The SPV signal can be detected by using an electrode 210 deposited on the sensing surface 114. The electrode 210 should not obstruct the sensing surface 114 so the molecules and light can freely interact with the sensing surface 114. The electrode 210 could be a grid-like conductor on the sensing surface 114 with some areas covered with conductor and others uncovered and freely exposed to interacting molecules and light.

SPV signal strength scales with the area of the sensing surface 114. Thus high sensor sensitivity can be achieved by employing a large surface area that is exposed to the molecules.

If the molecules being sensed are of a single species, the SPV signal can be calibrated to indicate molecule density, since the strength of the SPV signal depends on the number of molecules in the vicinity of the sensing surface. A physical technique such as X-ray photoelectron spectroscopy (XPS) can be used to obtain a relatively precise determination of the number of molecules on the sensing surface 114.

Returning to FIG. 1, there are various ways of enhancing the selectivity of the sensor 110 to certain types of molecules. One way is to use a functional coating 128 on the sensing surface 114. The functional coating 128 may be a molecular monolayer (or close to monolayer) layer of intermediary species placed at the sensing surface 114. The functional coating 128 either does not change V_{SENSdark} or at the sensing surface 114 it changes the sensing surface potential barrier (V_{SENS}) in a predictable and stable fashion (if the functional coating 128 changes the surface barrier in a stable and predictable manner, this effect can be accounted for in the final quantification of the sensed species), while simultaneously promoting interaction between the sensing surface 114 and only the selected molecule(s), preventing other molecules from interacting with the sensing surface 114, and decreasing interference from other undesirable surface interactions. Thus the functional coating 128 can make the detection scheme molecule-specific.

One example of a functional coating composition is an avidin/strepavidin-biotin system. Usually avidin or strepavidin is immobilized by adsorption on the sensing surface 114, and then a biomolecule functionalized with a biotin group can be attached to the sensing surface 114 with high affinity. Alternatively, the biotin can be first immobilized on the surface and then this surface can be used to detect avidin or strepavidin. Another example is the DNA hybridization. A single strand DNA can be immobilized on the sensing surface 114 when the complementary single strand DNA molecule is exposed to the sensing surface 114, whereby double helix DNA can form with extremely high selectivity.

Another way of enhancing the selectivity is through proper selection of the semiconductor material. A variety of semiconductors can be employed to obtain the desired interaction between the sensing surface 114 and selected molecules. In addition or in the alternative, the selectivity may be enhanced through proper selection of crystal orientation. For example, when sensing inorganic bases and acids, a stronger change of the SPV signal has been observed for <111> crystal orientation of silicon semiconductor than for a Si<100> crystal orientation or a Si<110> crystal orientation.

The selectivity of the molecule sensor 110 may be enhanced by also illuminating the sensing surface 114 with secondary illumination in addition to the primary illumination provided by the light source 118. The secondary illumination, provided by a second light source 130, causes the charge distribution of a specific type of molecule to change independent of the primary illumination. The change in charge distribution, in turn, modifies the change in the SPV. The secondary illumination interacts with the molecules on the sensing surface 114, but (under suitable conditions) does not directly change the band bending within the semiconductor 112. The secondary illumination should contain a narrow enough range of energies, including the energy corresponding to the specific type of molecule, but excluding the energies corresponding to other molecules that might be present.

Interpretation of the SPV signal can be simplified by turning the secondary illumination on and off during the SPV measurements. For example, first and second types of molecules are present on the sensing surface 114, but only the first molecule has the property of modifying the SPV signal when additionally illuminated with the secondary illumination. Measurements performed with and without the secondary illumination can help determine whether both molecules are present. With appropriate calibration of the SPV signal, the molecule types could be quantified.

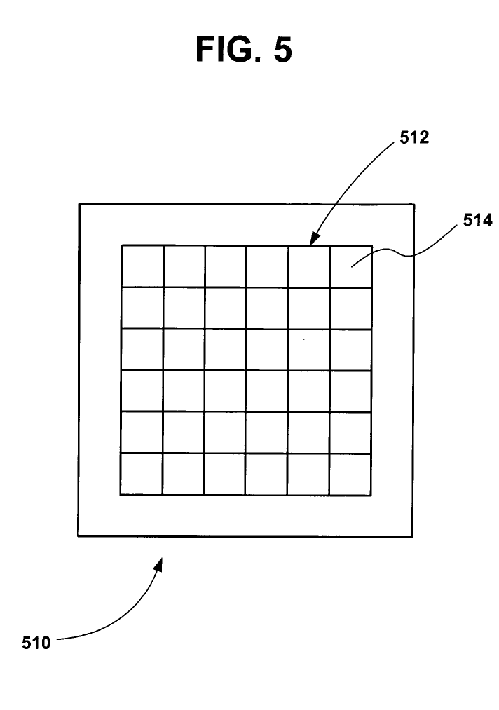

The molecule sensor 110 can be reused by refreshing the sensing surface 114 after the surface photovoltage is sensed. Adsorbed or surface-reacted molecules are removed, and the surface charges are restored to their original state. This could be accomplished in a variety of ways. A heating element proximate the molecule sensor 110 could be used to raise the semiconductor temperature to a point at which all the surface species are released. For example, a heating element 310 could be placed in contact with the electrode 124 (see FIG. 3). As an alternative, a UV light source 410 (for example, UV-LED) could be used to activate the surface species, forcing them to leave the sensing surface 114 (see FIG. 4). Additional blowing of gas 412 (also shown in FIG. 4). or flushing with liquid not containing the species to be sensed (i.e., an inert ambient) could flush the released species from the vicinity of the sensing surface 114, preventing their readsorption and repeated surface reaction and restore the surface potential to a well-established background level.

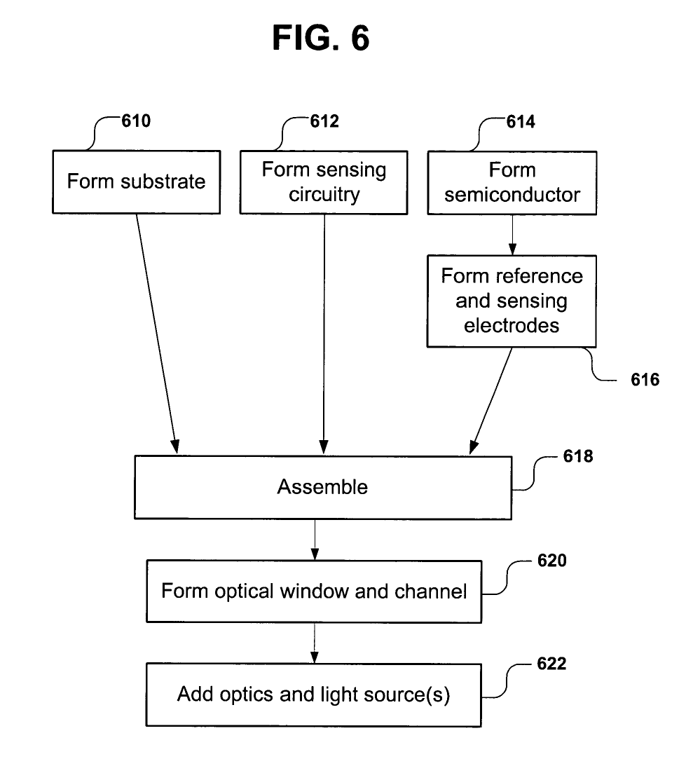

Reference is now made to FIG. 5, which illustrates a system 510 including an array 512 of molecule sensors 514. Each molecule sensor 514 may be of the type described above. However, different sensors 514 can be made to have different sensitivities, and to be sensitive to different types of molecules. Different molecule sensors 514 could be made of different semiconductor materials, or different molecule sensors 514 could be made of the same semiconductor material, but different crystal orientations. In addition or in the alternative, different molecule sensors 514 could have different functional coatings; or some molecule sensors 514 could be provided with functional coatings (the same or different), while other sensors are not provided with functional coatings.

By mathematically combining the signals from the different sensors 514, the sensor array 512 can perform simultaneous detection of a variety of different molecules. Computational methods can be used to differentiate the species, potentially reducing requirements on selectivity of the functional coating and increasing defect tolerance. For example, if a mixture being sensed contains a first species and a second species, and the functional coating makes the first species adhere to the sensing surface more readily than the second species, a series of calibration tests can be conducted by measuring SPV as a function of a ratio of the first species to the second species, combined with a combinatorial analysis. A calibrated signal could indicate the amount of the first species relative to the second species.

If functional coatings are used with a single semiconductor material, the sensors 514 could be illuminated with a single light source. If different semiconductor materials are used, multiple light sources generating light at different wavelengths can be used.

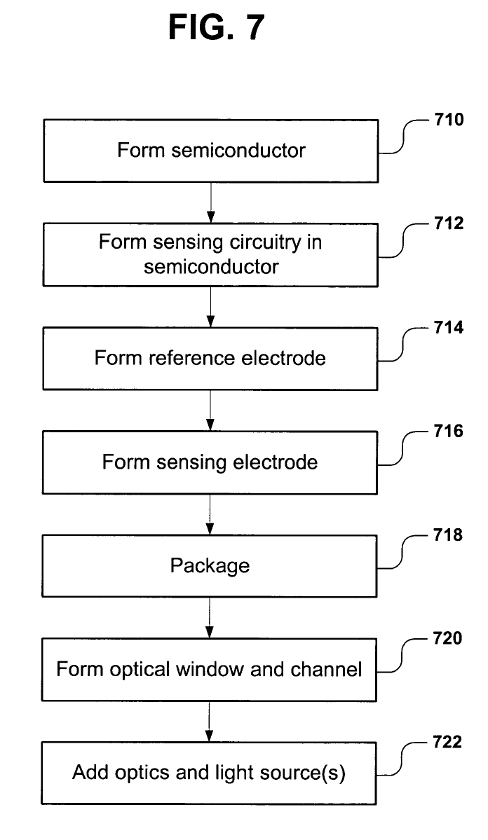

Reference is made to FIG. 6, which illustrates a method of manufacturing a hybrid sensing system. The method includes forming a substrate (610), forming a sensing circuit (612), and forming a semiconductor (614). The semiconductor is not formed on the sensing circuit. In addition to sensing the change in SPV, the sensing circuit can be designed to control other functions of the sensor (e.g., controlling the illumination, controlling the means for refreshing the sensing surface, etc.). The method further includes forming reference and sensing electrodes (616), and assembling the semiconductor (with the electrodes) and the sensing circuit on the substrate (618). An optical window that exposes the sensing surface to illumination is formed, as is a channel that freely exposes the sensing surface to molecules (620). Optics and light source(s) are added (622). The optics directs the illumination from the light source(s) to the sensing surface.

Reference is made to FIG. 7, which illustrates a method of manufacturing a monolithic sensing system. A semiconductor is formed (710). The semiconductor of the monolithic system combines the semiconductor and substrate of the hybrid system. Sensing circuitry is formed in the semiconductor (712), a back electrode is formed in contact with one surface of the semiconductor (714), and a sensing electrode is formed on or proximate an opposing surface of the semiconductor (716). The resulting structure is packaged (718), an optical window and channel are formed in the package (720), and optics and light source(s) are added (722).

Thus disclosed is a sensor that can detect the presence of selected biological and chemical species in real time. The sensor can be made selectively sensitive to a wide variety of chemical and biological species.

The sensor has a simple design that can be manufactured at relatively low cost. The sensor can be manufactured by using well-established semiconductor manufacturing techniques. The sensor has a small size, and can be integrated with electronic circuitry.

The sensor can also be made reusable, since the surface can be refreshed. The reusability lowers the cost of ownership

The sensor is not limited to any particular application. Chemical and biological sensing for homeland security is but one application.

Although several specific embodiments of the present invention have been described and illustrated, the present invention is not limited to the specific forms or arrangements of parts so described and illustrated. Instead, the present invention is construed according to the claims that follow.

1. A method of sensing molecules, the method comprising:
exposing a surface of a semiconductor to the molecules; and
sensing a change in surface photovoltage of the semiconductor.

2. The method of claim 1, wherein the change in surface photovoltage is sensed to determine molecule identity.

3. The method of claim 1, wherein the change in surface photovoltage is sensed to determine molecule quantity.

4. The method of claim 1, further comprising illuminating the exposed semiconductor surface while sensing the change in surface photovoltage.

5. The method of claim 4, wherein the semiconductor has a bandgap, and wherein the surface is illuminated with light of photon energy greater than or equal to the semiconductor bandgap.

6. The method of claim 4, further comprising illuminating the exposed surface with additional illumination having a wavelength that enhances interaction between a specific type of molecule and the exposed surface, whereby the sensed surface photovoltage determines the presence of the specific type among the molecules being sensed.

7. The method of claim 1, further comprising enhancing interaction between a specific type of molecule and the exposed surface.

8. The method of claim 7, wherein a functional coating is used to enhance the interaction.

9. The method of claim 7, wherein the interaction is enhanced by selection of material for the semiconductor.

10. The method of claim 1, wherein the sensing includes generating an electrical signal related to the change in surface photovoltage.

11. The method of claim 10, wherein generating the signal includes using a light transparent electrode in contact with the exposed surface, the electrode partially covering the surface.

12. The method of claim 10, wherein generating the signal includes using a grid-like electrode in contact with the exposed surface.

13. The method of claim 10, wherein the sensing includes using an electrode that is capacitively coupled to the semiconductor and that does not make contact with the exposed surface, the electrode not interfering with the interaction of molecules at the surface; and measuring capacitance between the electrode and the semiconductor.

14. The method of claim 10, further comprising illuminating the surface with an ac light probe and creating an electrical ac reference; and wherein the sensing includes enhancing the signal at the frequency corresponding to the ac reference.

15. The method of claim 1, further comprising refreshing the surface of the semiconductor after the surface photovoltage is sensed.

16. A molecule sensor comprising:
a semiconductor having a sensing surface; and
a circuit for sensing a change in surface photovoltage of the semiconductor.

17. The sensor of claim 16, further comprising a light source for illuminating the sensing surface with light of photon energy greater than or equal to semiconductor bandgap.

18. The sensor of claim 17, further comprising a second light source for illuminating the sensing surface with additional illumination having a wavelength that enhances interaction between a specific type of molecule and the sensing surface.

19. The sensor of claim 16, further comprising means for enhancing interaction between a specific type of molecule and the sensing surface.

20. The sensor of claim 16, further comprising a functional coating on the sensing surface.

21. The sensor of claim 20, wherein the functional coating includes functionalized biomolecules immobilized on the sensing surface.

22. The sensor of claim 20, wherein the functional coating includes single strand DNA immobilized on the sensing surface.

23. The sensor of claim 16, wherein material for the semiconductor enhances interaction between a specific type of molecule and the sensing surface.

24. The sensor of claim 16, further comprising an electrode in electrical communication with the sensing surface and the circuit.

25. The sensor of claim 24, wherein the electrode is light transparent and in contact with the sensing surface, the electrode partially covering the surface.

26. The sensor of claim 24, wherein the electrode is grid-like and in contact with the sensing surface.

27. The sensor of claim 24, wherein the electrode is spaced apart from and capacitively coupled to the semiconductor, the electrode not interfering with the interaction of molecules at the sensing surface; the circuit measuring capacitance between the electrode and the semiconductor.

28. The sensor of claim 16, further comprising a source for illuminating the surface with an ac light probe; the circuit creating an electrical ac reference and enhancing the signal at the frequency corresponding to the ac reference.

29. The sensor of claim 16, further comprising means for refreshing the sensing surface after the surface photovoltage is sensed.

30. The sensor of claim 16, further comprising a source for illuminating the sensing surface with ultraviolet radiation after the change in surface photovoltage is sensed.

31. The sensor of claim 16, further comprising a heating element coupled to a reference surface of the semiconductor for heating the semiconductor.

32. The sensor of claim 16, further comprising a source for providing a species-removing fluid over the sensing surface after the change in surface photovoltage is sensed.

33. A system for detecting molecules, the system comprising:
a plurality of sensors, each sensor including a semiconductor having a sensing surface;
at least one light source for illuminating the sensing surfaces of the sensors; and
a circuit for sensing a change in surface photovoltage of the semiconductors while the sensing surfaces exposed to the molecules.

34. The system of claim 33, wherein at least some of the sensors are sensitive to different types of molecules.

35. The system of claim 33, wherein at least some of the sensors have different sensitivities to the same type of molecule.

36. The system of claim 33, further comprising optics for directing the illumination onto the sensing surfaces.

37. The system of claim 33, wherein the circuitry is formed in the semiconductor whereby the system is monolithic.

38. The system of claim 33, wherein the semiconductor and circuit are separate, whereby the system is a hybrid.

39. The system of claim 33, wherein the light source provides light of photon energy greater than or equal to semiconductor bandgaps of the sensors.

40. The system of claim 33, further comprising means for enhancing interaction between at least one specific type of molecule and the sensing surfaces of the sensors.

41. The system of claim 33, further comprising electrode means in electrical communication with the circuit and the sensing surfaces of the sensors.

42. The system of claim 33, further comprising means for refreshing the sensing surfaces of the sensors.
